(19) United States
(12) Patent Application Publication
(10) Pub. No.: US 2026/0025258 A1
(43) Pub. Date: Jan. 22, 2026

(54) CIRCUIT AND METHOD FOR DIGITAL CLOCK DATA RECOVERY

(71) Applicant: Montage Electronics (Shanghai) Co., Ltd., Shanghai (CN)

(72) Inventors: Guokai YI, Shanghai (CN); Yuanfei NIE, Shanghai (CN)

(73) Assignee: Montage Electronics (Shanghai) Co., Ltd., Shanghai (CN)

(21) Appl. No.: 19/269,077

(22) Filed: Jul. 15, 2025

(30) Foreign Application Priority Data
Jul. 17, 2024 (CN) 2024109633944

(51) Int. Cl. H04L 7/02; H03L 7/08; H03L 7/085

(52) U.S. Cl. CPC H04L 7/02; H03L 7/0807; H03L 7/085

(57) ABSTRACT

A circuit and a method for digital clock data recovery are provided. The circuit comprises an analog-to-digital converter, an error detector, a frequency deviation detector, a loop filter, a phase code generator, and a phase interpolator. The analog-to-digital converter samples an analog input signal under the control of a sampling clock signal to obtain a sampled signal, and converts the sampled signal into a digital signal. The error detector performs phase error detection based on the digital signal to obtain phase error estimation values. The frequency deviation detector obtains a frequency deviation estimation value based on the phase error estimation values. The loop filter filters and outputs a filtered signal based on the phase error estimation values and the frequency deviation estimation value. The phase code generator generates a phase code based on the filtered signal. The phase interpolator generates the sampling clock signal based on the phase code.

### FIELD OF THE INVENTION

The present disclosure relates to the technical field of clock data recovery, and relates to a circuit for digital clock data recovery, in particular to a circuit and a method for digital clock data recovery.

### BACKGROUND OF THE INVENTION

Clock data recovery (CDR) is a crucial technology in digital communications, primarily used to extract an accurate clock signal from input data, which then helps to recover and synchronize the data. Within a limited range of frequency deviation (the difference between the sampling clock frequency and the input data clock frequency), phase error-based CDR circuits can effectively capture such deviation. However, as communication rates increase, loop delay grows due to circuit parameters, and the convergence frequency range of CDR circuits decreases. Meanwhile, the frequency deviation caused by clock differences continues to increase, which results in longer capture time for phase error-based CDR circuits, or may require multiple initializations with different frequency deviations to properly capture the frequency deviation, potentially even locking onto an incorrect bias frequency. In other words, existing phase error-based CDR circuits are not suitable for applications with large frequency deviations, especially in scenarios with spread spectrum clocking (SSC).

Therefore, quickly and accurately capturing frequency deviations in scenarios with large frequency deviations remains an urgent problem to be solved.

### SUMMARY OF THE INVENTION

The present disclosure provides a circuit and a method for digital clock data recovery, which enable the quick and accurate capture of clock frequency deviations in scenarios with large frequency deviations.

A first embodiment of the present disclosure provides a circuit for digital clock data recovery, comprising an analog-to-digital converter, an error detector, a frequency deviation detector, a loop filter, a phase code generator, and a phase interpolator. The analog-to-digital converter is configured to sample an analog input signal under the control of a sampling clock signal to obtain a sampled signal, and convert the sampled signal into a digital signal. The error detector is configured to perform phase error detection based on the digital signal to obtain one or more phase error estimation values. The frequency deviation detector is configured to obtain a frequency deviation estimation value based on the phase error estimation values. The loop filter is configured to filter and output a filtered signal based on the phase error estimation values and the frequency deviation estimation value. The phase code generator is configured to generate a phase code based on the filtered signal. The phase interpolator is configured to generate the sampling clock signal based on the phase code to control a sampling phase of the analog-to-digital converter.

In some examples of the present disclosure, the phase interpolator adjusts a phase of a local reference clock based on the phase code to generate the sampling clock signal.

In some examples of the present disclosure, the frequency deviation detector comprises a pre-processing unit, a differential calculation unit, and a frequency deviation calculation unit. The pre-processing unit is configured to pre-process the phase error estimation values to obtain pre-processed phase error estimation values. The differential calculation unit is configured to obtain a differential sequence based on the pre-processed phase error estimation values. The frequency deviation calculation unit is configured to calculate the frequency deviation estimation value based on the differential sequence.

In some examples of the present disclosure, the differential sequence is an indication signal for occurrences of phase error estimation value jumps.

In some examples of the present disclosure, the differential calculation unit calculates the indication signal by following formulas:

$$f ( i ) = compare ( s ( i ) - s ( i - τ ) , th 1 ) ; and$$

$$compare ( s ( i ) - s ( i - τ ) , th 1 ) = \{ \begin{matrix}\begin{matrix}sign ( s ( i ) - s ( i - τ ) ) , & if abs ( s ( i ) - s ( i - τ ) ) > th 1\end{matrix} \\ \begin{matrix}0 , & else\end{matrix}\end{matrix} ;$$

where f(i) represents the indication signal, s(i) represents the pre-processed phase error estimation values, th1 represents a first threshold value, t represents a time interval between two adjacent phase error estimation values, and sign represents a symbol function.

In some examples of the present disclosure, the frequency deviation calculation unit is configured to calculate the frequency deviation estimation value based on an integral of the indication signal over a specific time interval.

In some examples of the present disclosure, the frequency deviation calculation unit calculates the frequency deviation estimation value by following formulas:

$$Δ f r q ( i ) = \{ \begin{matrix}est ( frqdetintg ( i ) ) , if mod ( i , T ) = 0 \\ 0 , else\end{matrix} ;$$

$$frqdetintg ( i ) = frqdetintg ( i - 1 ) + f ( i ) ; and$$

$$est ( fr q d e t i n t g ( i ) ) = frqslp * floor ( \frac{frqdetintg ( i )}{frqth} + 0.5 ) ;$$

where Δfrq(i) represents the frequency deviation estimation value, frqdetintg(i) represents an accumulated indication signal for the occurrence of phase error estimation value jumps, f(i) represents the indication signal for the occurrences of phase error estimation value jumps, mod represents a remainder function, T represents the specific time interval, frqslp represents a slope of the integral of the indication signal, floor represents a downward rounding function, and frqth represents an accumulated count threshold for the occurrences of phase error estimation value jumps.

In some examples of the present disclosure, the frequency deviation calculation unit is configured to calculate the frequency deviation estimation value based on a duration required for integrating the indication signal to an upper limit value or a lower limit value.

In some examples of the present disclosure, the loop filter is a second-order filter.

In some examples of the present disclosure, a frequency integral branch of the second-order filter is given by:

$$intg ( i ) = intg ( i - 1 ) + β * t e d ( i ) + Δ f r q ( i ) ;$$

where intg(i) represents an output of the loop filter at moment i, intg(i−1) represents an output of the loop filter at moment (i−1), β represents a coefficient, ted(i) represents the phase error estimation values, and Δfrq(i) represents the frequency deviation estimation value.

In some examples of the present disclosure, when a detection frequency of the frequency deviation detector reaches a detection threshold and the frequency deviation estimation value is detected to be less than a second threshold, the frequency deviation detector is turned off, and the loop filter obtains the filtered signal based on the phase error estimation values.

In some examples of the present disclosure, a quantity of the phase error estimation values is more than one, and the frequency deviation detector obtains the frequency deviation estimation value based on an average value of the phase error estimation values.

A second embodiment of the present disclosure provides a digital clock data recovery method, applied to a circuit for digital clock data recovery. The circuit comprises an analog-to-digital converter, an error detector, a frequency deviation detector, a loop filter, a phase code generator, and a phase interpolator. The method comprises: sampling, by the analog-to-digital converter, an analog input signal under the control of a sampling clock signal to obtain a sampled signal, and converting the sampled signal into a digital signal; performing, by the error detector, phase error detection based on the digital signal to obtain one or more phase error estimation values; obtaining, by the frequency deviation detector, a frequency deviation estimation value based on the phase error estimation values; filtering and outputting, by the loop filter, a filtered signal based on the phase error estimation values and the frequency deviation estimation value; generating, by the phase code generator, a phase code based on the filtered signal; and generating, by the phase interpolator, the sampling clock signal based on the phase code.

### BRIEF DESCRIPTION OF DRAWINGS

FIG. 1 is a schematic diagram of a frequency deviation between an erroneously locked clock frequency and an actual clock frequency in a large frequency deviation scenario.

FIG. 2A is a schematic structural diagram of a circuit for digital clock data recovery according to an embodiment of the present disclosure.

FIG. 2B is a schematic diagram of a sampling clock frequency transitioning from erroneously locked at a bias frequency to successfully locked at an actual clock frequency according to an embodiment of the present disclosure.

FIG. 3A shows a relationship between sampling phases and phase error estimation values when a data frequency is correctly locked according to an embodiment of the present disclosure.

FIG. 3B shows a relationship between sampling phases and the phase error estimation values in a large frequency deviation scenario according to an embodiment of the present disclosure.

FIG. 4 is a schematic structural diagram of a frequency deviation detector according to an embodiment of the present disclosure.

FIG. 5 is a simulation diagram showing a relationship between frqdetintg and actual frequency deviation according to an embodiment of the present disclosure.

FIG. 6 is a flowchart of a method for digital clock data recovery according to an embodiment of the present disclosure.

### DETAILED DESCRIPTION OF THE INVENTION

The embodiments of the present disclosure will be described below. Those skilled can easily understand other advantages and effects of the present disclosure according to contents disclosed by the specification. The present disclosure can also be implemented or applied through other different specific embodiments. Various details in this specification can also be modified or changed based on different viewpoints and disclosures without departing from the spirit of the present disclosure. It should be noted that the following embodiments and features of the following embodiments can be combined with each other if no conflict will result.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the layout of the components can also be more complicated.

In the following detailed description, the terms like “first” and “second” are used for indication purpose only and should not be construed as indicating or implying relative importance or implicitly specifying numbers of technical features indicated. Thus, features qualified with terms like “first” and “second” may explicitly or implicitly include at least one such feature. In the present disclosure, “a plurality of” means two or more, unless otherwise expressly specified.

In the present disclosure, unless otherwise expressly specified, terms such as “connection” and “coupling” should be broadly understood. For example, when one element is referred to as being “connected to” another element, one element may be mechanically connected to or electrically connected to another element, may be directly connected to another element, or may be indirectly connected to another element with another element interposed therebetween. These two elements may also communicate with each other internally or interact with each other. Those of ordinary skill in the art can understand the specific meanings of the above terms in the present disclosure according to specific situations.

For clock data recovery (CDR) circuits, loop locking refers to a state in which the control loop in the CDR circuit successfully locks onto the clock frequency (also referred to as data frequency) and phase of the input data, and maintains this locked state. When there is a large frequency deviation between a sampling clock frequency and a data frequency, achieving loop locking becomes challenging, potentially resulting in either failure to lock or erroneous locking.

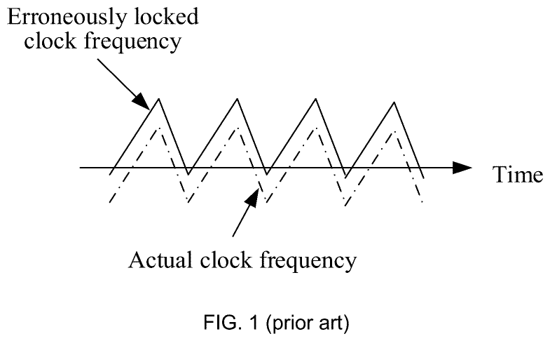

In the case of erroneous locking, the large frequency deviation causes the sampling phase to rapidly traverse the entire period. The values of the phase error detection signal (e.g., timing error detection signal) will repeatedly traverse from positive to negative or from negative to positive, causing the frequency integral to be zero, thereby resulting in a fixed deviation between the sampling clock frequency and the data frequency. In FIG. 1, the “Actual clock frequency” represents the data frequency, while the “Erroneously locked clock frequency” indicates the sampling clock frequency. When erroneous locking occurs, the CDR circuit needs to be tested and reset, which affects clock synchronization and prolongs the duration required to achieve a normal reception state. Some technical solutions address erroneous locking by adding a frequency discriminator; however, this approach has high computational demands and stringent delay requirements, leading to high implementation costs.

In the case of failure to lock, the CDR circuit cannot successfully lock onto the clock frequency and phase of the input data, preventing the receiving end from correctly sampling the data and resulting in reception failure.

To solve the above-mentioned shortcomings, a circuit for digital clock data recovery is provided. The present disclosure will be described in further detail below with reference to the accompanying drawings.

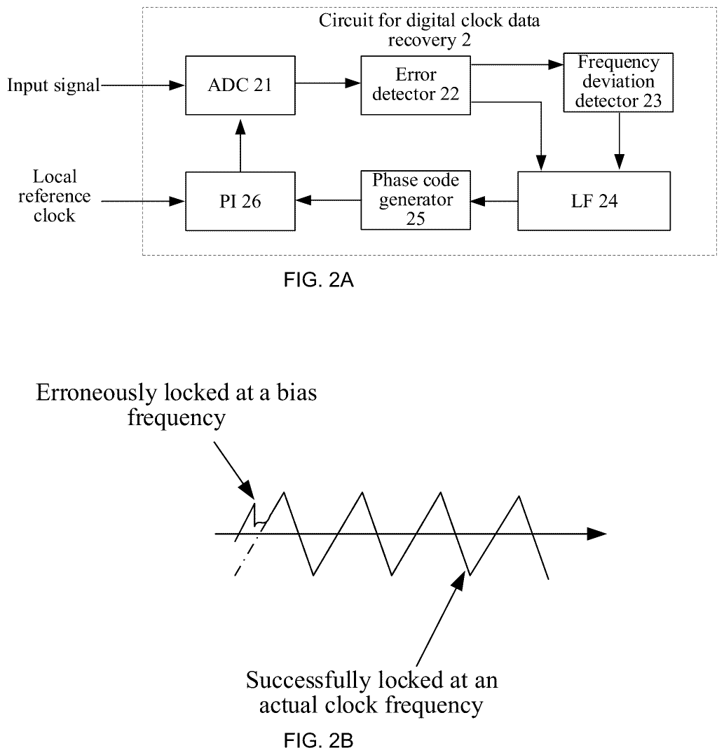

FIG. 2A is a schematic structural diagram of a circuit 2 for digital clock data recovery according to an embodiment of the present disclosure. As shown in FIG. 2A, the circuit 2 comprises an analog-to-digital converter (ADC) 21, an error detector 22, a frequency deviation detector 23, a loop filter (LF) 24, a phase code generator 25, and a phase interpolator (PI) 26.

The ADC 21 is used to sample an analog input signal under the control of a sampling clock signal to obtain a sampled signal, and convert the sampled signal into a digital signal for subsequent signal processing and clock recovery.

The error detector 22 is used to perform phase error detection based on the digital signal output by the ADC 21 to obtain one or more phase error estimation values. The phase error estimation values are used to indicate an offset value of a sampling phase corresponding to the analog input signal relative to an ideal sampling phase, and the ideal sampling phase is an intermediate phase over a unit interval (UI), i.e., 1UI.

In some embodiments, the error detector 22 can use a high sampling rate-based BB-like (Barzilai-Borwein-like) algorithm or a baud rate-based MM-like (majorization-minimization-like) algorithm for phase error detection.

In some embodiments, the error detector 22 can be a phase error detector (PED) or a timing error detector (TED).

The phase error estimation values detected by the error detector 22 are output to both the frequency deviation detector 23 and the LF 24.

The frequency deviation detector 23 is used to obtain a frequency deviation estimation value based on the phase error estimation values. The working principle of the frequency deviation detector 23 will be explained in detail below.

The LF 24 is used to filter a signal and output the filtered signal based on the phase error estimation values from the error detector 22 and the frequency deviation estimation value from the frequency deviation detector 23. The filtered signal represents the frequency deviation between the sampling clock frequency and the data frequency.

The phase code generator 25 is used to generate a phase code based on the filtered signal. In some embodiments, the phase code can be an interpolation phase code for the PI 26.

The PI 26 is used to generate the sampling clock signal based on the phase code to control the sampling phase of the ADC 21.

In some embodiments, a local reference clock can be used, and the PI 26 can adjust a phase of the local reference clock based on the phase code to generate the sampling clock signal.

The circuit 2 of the present disclosure can quickly achieve loop locking. FIG. 2B is a schematic diagram of the sampling clock frequency transitioning from erroneously locked at a bias frequency to successfully locked at an actual clock frequency according to an embodiment of the present disclosure. This highlights that the circuit of the present disclosure can efficiently achieve clock synchronization, significantly shortening the duration required for a receiving end to reach a normal reception state.

Next, the principle of the frequency deviation detector 23 will be introduced. Specifically, when the error detector 22 performs phase error detection, the phase error estimation values output by the error detector 22 vary based on the different sampling phases. When sampled at the ideal sampling phase, the phase error estimation value is zero. When sampling is advanced, the phase error estimation value is a positive value. When sampling is lagged, the phase error estimation value is a negative value.

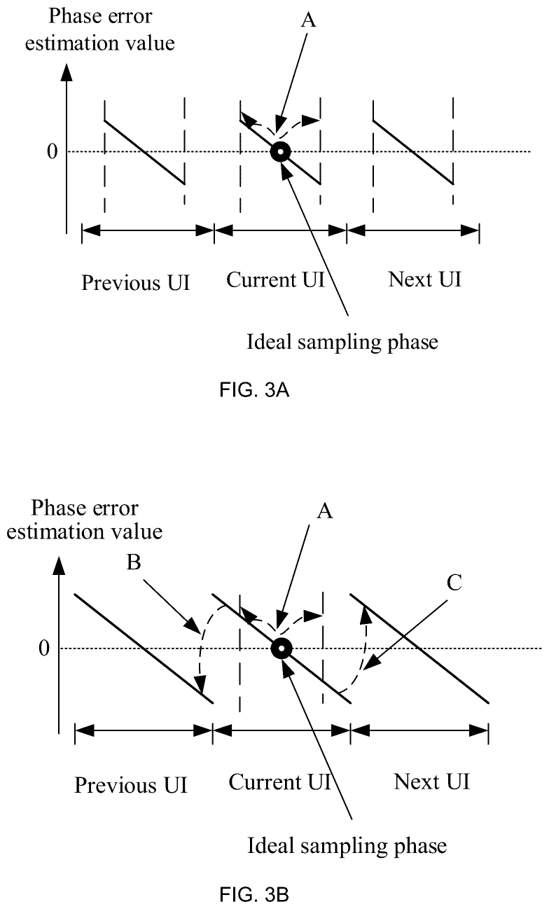

FIG. 3A shows a relationship between sampling phases and phase error estimation values when the data frequency is correctly locked. The horizontal axis represents the sampling phases corresponding to different UIs, while the vertical axis shows the phase error estimation values output by the error detector 22. As shown in FIG. 3A, when the data frequency is correctly locked, the sampling phases fluctuate within Region A, during which time, the phase error estimation values remain stable within a narrow range, and the phase error estimation values of adjacent UIs are closely aligned.

FIG. 3B shows a relationship between sampling phases and phase error estimation values in a large frequency deviation scenario, with the horizontal axis representing the sampling phases corresponding to different UIs, and the vertical axis showing the phase error estimation values output by the error detector 22. As shown in FIG. 3B, when there is a large deviation between the sampling clock frequency and the data frequency, the sampling phases may sweep across the entire UI or even flip between UIs, in which case, the error detector 22 periodically outputs values that transition from negative to positive or from negative to positive, thereby resulting in a large difference between the phase error estimation values, with noticeable polarity reversals between adjacent estimation values (e.g., jumping from a negative maximum to a positive maximum, or from a positive maximum to a negative maximum), as indicated by Arrow B and Arrow C in FIG. 3B. If the sampling clock frequency is lower than the data frequency, the transition marked by Arrow B occurs. Conversely, if the sampling clock frequency is higher than the data frequency, the transition indicated by Arrow C takes place. Additionally, the interval between these transitions is directly proportional to the magnitude of the frequency deviation. Based on this, the frequency deviation detector 23 can determine if the data frequency is correctly locked by detecting such transitions in phase error estimation values. Furthermore, when the data frequency is not locked or is incorrectly locked, the frequency deviation detector 23 can estimate the frequency deviation by measuring the transition interval, thus obtaining the frequency deviation estimation value. The transition interval refers to the time interval between two occurrences where the phase error estimation value transition from positive to negative or from negative to positive.

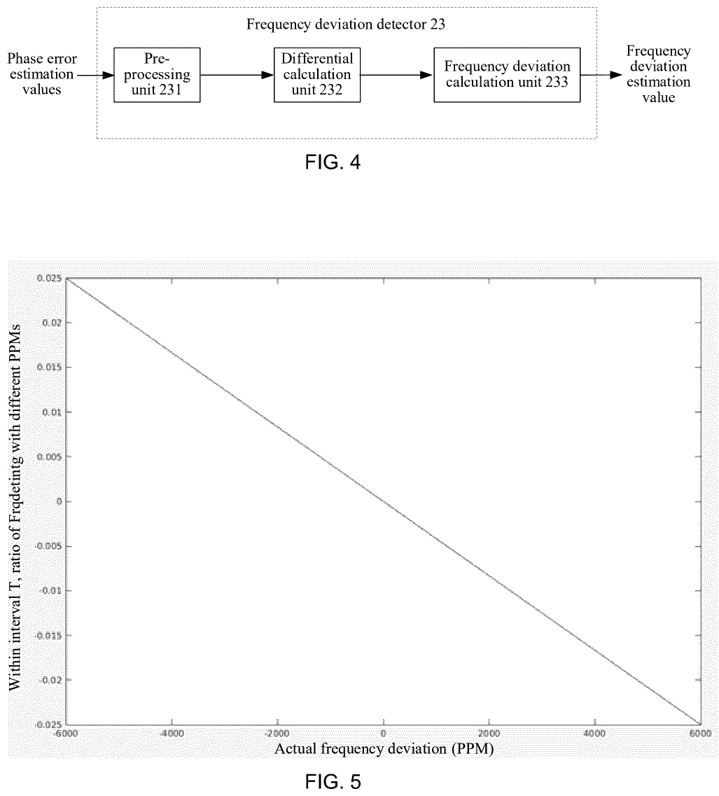

Referring to FIG. 4, in some embodiments, the frequency deviation detector 23 comprises a pre-processing unit 231, a differential calculation unit 232, and a frequency deviation calculation unit 233. The pre-processing unit 231 is used to pre-process the phase error estimation values to obtain pre-processed phase error estimation values for noise reduction. The differential calculation unit 232 is used to obtain a differential sequence based on the pre-processed phase error estimation values, and the differential sequence indicates slopes of the changing phase error estimation values. The frequency deviation calculation unit 233 is used to calculate the frequency deviation estimation value based on the differential sequence.

Exemplarily, the pre-processing unit 231 can function as a Low-pass Filter (LPF). The LPF applies low-pass filtering to the phase error estimation values, as expressed in formula (1):

$$s ( i ) = t e d ( i ) * α + s ( i - 1 ) * ( 1 - α ) , \qquad ( 1 ) ;$$

where s(i) represents an output of the pre-processing unit 231 at moment i, ted(i) represents the phase error estimation value output by the error detector 22, α represents is the LPF coefficient, and s(i−1) represents an output of the pre-processing unit 231 at moment (i−1).

Exemplarily, the pre-processing unit 231 can also operate as a Median Filter (MF).

It is important to note that the LPF and MF are only two examples of how the pre-processing unit 231 can be implemented in the present disclosure.

In some embodiments, the differential sequence is an indication signal for occurrences of phase error estimation value jumps. The differential calculation unit 232 calculates the indication signal using formulas (2) and (3):

$$f ( i ) = compare ( s ( i ) - s ( i - τ ) , th 1 ) , \qquad ( 2 ) ;$$

$$compare ( s ( i ) - s ( i - τ ) , th 1 ) = \{ \begin{matrix}\begin{matrix}sign ( s ( i ) - s ( i - τ ) ) , & if abs ( s ( i ) - s ( i - τ ) ) > th 1\end{matrix} \\ \begin{matrix}0 , & else\end{matrix}\end{matrix} , \qquad ( 3 ) ;$$

where f(i) represents the indication signal, s(i) represents the pre-processed phase error estimation values, t represents a time interval between two adjacent phase error estimation values, th1 represents a first threshold value, which can be set based on practical requirements or experience, sign represents a symbol function, and abs represents an absolute value function.

In some embodiments, the frequency deviation calculation unit 233 is used to calculate the frequency deviation estimation value based on an integral of the indication signal over a specific time interval.

Exemplarily, the frequency deviation calculation unit 233 can determine the frequency deviation estimation value using formulas (4) to (6):

$$Δ frq ( i ) = \{ \begin{matrix}est ( frqdetintg ( i ) ) , if mod ( i , T ) = 0 \\ 0 , else\end{matrix} , \qquad ( 4 ) ;$$

$$frqdetintg ( i ) = frqdetintg ( i - 1 ) + f ( i ) , \qquad ( 5 ) ;$$

est represents a lookup operation, and its mapping relationship can be defined by formula (6):

$$est ( frq d e t i n t g ( i ) ) = frqslp * floor ( \frac{frqdetintg ( i )}{frqth} + 0.5 ) , \qquad ( 6 ) ;$$

where Δfrq(i) represents the frequency deviation estimation value, frqdetintg(i) represents an accumulated indication signal for the occurrence of phase error estimation value jumps, mod represents a remainder function, T represents the specific time interval, and floor represents a downward rounding function;

$$floor ( \frac{frqdetintg ( i )}{frqth} + 0 \text{.5} ) rounds \frac{frqdetintg ( i )}{frqth}$$

to the nearest integer; frqth represents an accumulated count threshold for the occurrences of phase error estimation value jumps, whose value is proportional to the specific time interval T,

$$\frac{frqdetintg ( i )}{frqth}$$

enabling to represent the ratio of the occurrences of phase error estimation value jumps within the specific time interval T; frqslp represents a slope of the integral of the indication signal, which can be either a constant or a value determined through practical needs. In some embodiments, the value of frqslp can also be estimated through simulation. FIG. 5 is a simulation diagram showing a relationship between frqdetintg and actual frequency deviation, where the slope represents frqslp.

Exemplarily, if a convergence boundary of the CDR circuit's frequency

$$T > \frac{1 e 6}{c drppmth} * 512 UI$$

deviation is cdrppmth (in ppm), the specific time interval T must Sausry to ensure adequate coverage and calculation accuracy for the frequency deviation range.

In some embodiments, instead of specifying the time interval T, an upper limit value and/or a lower limit value for frqdetintg can be set. The frequency deviation estimation value can then be calculated based on the duration it takes for frqdetintg to reach these limit values. Specifically, larger frequency deviations result in faster integration of the indication signal. Based on this, the frequency deviation calculation unit 233 can calculate the frequency deviation estimation value either by integrating the indication signal over the specific time interval T, or by determining the duration required for integrating the indication signal to the upper limit value or lower limit value.

It is worth mentioning that there are various methods for the frequency deviation calculation unit 233 to calculate the frequency deviation estimation value. The approaches described above are just two examples.

In some embodiments, the LF 24 is a second-order filter. A frequency integral branch of the second-order filter can be represented by formula (7):

$$intg ( i ) = intg ( i - 1 ) + β * t e d ( i ) + Δ f r q ( i ) , \qquad ( 7 ) ;$$

where intg(i) represents an output of the LF 24 at moment i, intg(i−1) represents an output of the LF 24 at moment (i−1), β represents a coefficient, which can be determined as needed, ted(i) represents the phase error estimation value output by the error detector 22, and Δfrq(i) represents the frequency deviation estimation value output by the frequency deviation detector 23. It can be seen that the filtered signal output by the LF 24 comprises both the frequency deviation estimation value calculated from the phase error estimation values and the frequency deviation estimation value provided by the frequency deviation detector 23. When there is a large frequency deviation between the sampling clock frequency and the data frequency, the phase error estimation values periodically alternate between negative and positive. As a result, the frequency deviation estimation value derived solely from the phase error estimation values may be zero. In such cases, relying exclusively on the phase error estimation values to calculate the frequency deviation will not produce the actual frequency deviation estimation value, at which time, the frequency deviation estimation value from the frequency deviation detector 23 can be utilized to reliably determine the frequency deviation between the sampling clock frequency and the data frequency.

In some embodiments, the LF 24 may adopt a multi-order Proportional-Integral (PI) structure, where the specific order can be determined based on practical requirements or experience.

In some embodiments, a detection threshold may be established. When a detection frequency of the frequency deviation detector 23 reaches a detection threshold and all the frequency deviation estimation values are below a second threshold, it indicates that the frequency deviation between the sampling clock frequency and the data frequency is minimal, at which time, the frequency deviation detector 23 is turned off, and the LF 24 obtains the filtered signal based on the phase error estimation values. Both the detection threshold and the second threshold can be adjusted according to actual needs or prior experience.

In some embodiments, a quantity of the phase error estimation values is more than one. For example, an ADC-based receiving end (ADC-based RX) may feature multiple analog-to-digital converters. Using the digital signals produced by these converters, the error detector can generate multiple phase error estimation values. The phase error estimation values from the error detector are output in blocks, with the digital computation clock corresponding to multiple cycles of the data clock. In some embodiments, the frequency deviation detector 23 obtains the frequency deviation estimation value based on an average value of the phase error estimation values.

As described above, the circuit of the present disclosure leverages the relationship between the time series of phase error estimation values and the frequency deviation estimation value, embeds the frequency deviation detector into a phase error-based CDR circuit, and calculates the slope of changes in phase error estimation values using the frequency deviation detector to estimate frequency deviation based on this slope. The frequency deviation estimated by the frequency deviation detector can quickly confine the remaining clock frequency deviation within the operating range of the CDR circuit, allowing the CDR circuit to rapidly track and capture the clock signal. This approach grants the CDR circuit a broader frequency deviation capture range, enabling the quick and accurate capture of frequency deviations in scenarios with large frequency deviations.

Moreover, clock frequency deviation tracking is limited by circuit delays, meaning high-speed digital receiving ends require faster processing clocks or fewer processing beats. By integrating the frequency deviation detector, the circuit of the present disclosure reduces timing requirements and enhances flexibility in circuit design.

Additionally, the circuit of the present disclosure only needs a frequency deviation detector added to the CDR circuit to significantly extend the locking range of frequency deviations, achieving low complexity and easy implementation.

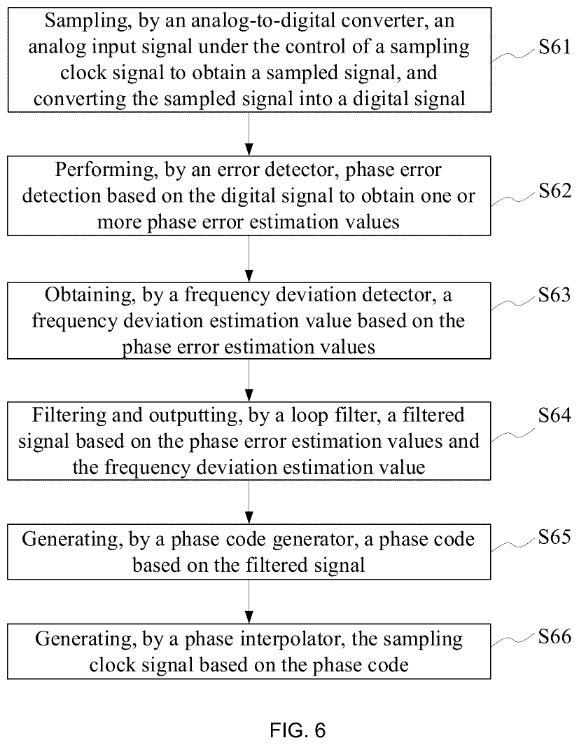

The present disclosure further provides a digital clock data recovery method, applied to a circuit for digital clock data recovery. FIG. 6 is a flowchart of the method of the present disclosure. As shown in FIG. 6, the method comprises steps S61 to S66.

Step S61 comprises: sampling, by an analog-to-digital converter, an analog input signal under the control of a sampling clock signal to obtain a sampled signal, and converting the sampled signal into a digital signal.

Step S62 comprises: performing, by an error detector, phase error detection based on the digital signal to obtain one or more phase error estimation values.

Step S63 comprises: obtaining, by a frequency deviation detector, a frequency deviation estimation value based on the phase error estimation values.

Step S64 comprises: filtering and outputting, by a loop filter, a filtered signal based on the phase error estimation values and the frequency deviation estimation value.

Step S65 comprises: generating, by a phase code generator, a phase code based on the filtered signal.

Step S66 comprises: generating, by a phase interpolator, the sampling clock signal based on the phase code.

It should be noted that steps S61 to S66 correspond directly to the respective modules in the circuit shown in FIG. 2A. Further details will not be repeated here.

The circuit for digital clock data recovery of the present disclosure leverages the relationship between the time series of phase error estimation values and the frequency deviation estimation value, sets the frequency deviation detector into a phase error-based CDR circuit, and enables the frequency deviation detector to calculate the slope of changes in phase error estimation values based on the phase error estimation values. The frequency deviation estimated by the frequency deviation detector can quickly confine the remaining clock frequency deviation within the operating range of the CDR circuit, allowing the CDR circuit to rapidly track and capture the clock signal. This approach grants the CDR circuit a broader frequency deviation capture range, enabling the quick and accurate capture of frequency deviations in scenarios with large frequency deviations.

Moreover, clock frequency deviation tracking is limited by circuit delays, meaning high-speed digital receiving ends require faster processing clocks or fewer processing beats. By integrating the frequency deviation detector, the circuit of the present disclosure reduces timing requirements and enhances flexibility in circuit design.

Additionally, the frequency deviation detector in the circuit of the present disclosure significantly extends the locking range of frequency deviations, achieving low complexity and easy implementation.

The scope of the method of the present disclosure is not limited to the sequence of operations listed herein. Any scheme realized by adding or subtracting operations or replacing operations of the traditional techniques according to the principle of the present disclosure is included in the scope of the present disclosure.

The circuit of the present disclosure can implement the digital clock data recovery method described in the present disclosure, but the device for implementing the digital clock data recovery method described in the present disclosure includes, but is not limited to, the circuit as described in the present disclosure. Any structural adjustment or replacement of the prior art made according to the principles of the present disclosure is included in the scope of the present disclosure.

In the several embodiments proposed in the present disclosure, the disclosed systems, devices, or methods can be implemented in other ways. For example, the embodiments of devices described above are only illustrative, and the division of modules or units is only a logical functional division. In actual implementation, there may be other division methods, such as multiple modules or units can be combined or integrated into another system, or some features can be ignored or not executed. Here, the coupling or direct coupling or communication connection between each other can be indirect coupling or communication connection through some interfaces, devices, modules, or units, and can be electrical connection, mechanical connection, or other connections.

The modules or units shown as separate components can be physically separated or not. The components shown as modules or units can be physical modules or not. That is, they can be located in one place, or they can also be distributed to multiple network units. Some or all of the modules or units can be selected as needed to achieve the purpose of the embodiment. For example, in one embodiment of the present disclosure, each functional module or unit can be integrated into one processing module. Each functional module or unit can exist physically separately, or two or more modules or units can be integrated into one module or unit.

The ordinary technical personnel in this field should further realize that the units and algorithm steps of each example described in combination with the embodiments disclosed here can be implemented by electronic hardware, computer software, or a combination of both. In the above description, each example's composition and steps have been described generally based on functions, so as to clearly illustrate the interchangeability of hardware and software. Whether these functions are executed by hardware or software depends on the specific application and design constraints of the technical solution. Professional technicians can use different methods to implement the functions described for each specific situation, but such implementation should not be considered beyond the scope of the present disclosure.

The descriptions of the steps or structures corresponding to the drawings are respectively emphasized, and some steps or structures that are not detailed can be referred to the relevant descriptions of other steps or structures.

The above-mentioned embodiments are merely illustrative of the principle and effects of the present disclosure instead of limiting the present disclosure. Modifications or variations of the above-described embodiments may be made by those skilled in the art without departing from the spirit and scope of the present disclosure. Therefore, all equivalent modifications or changes made by those skilled in the art without departing from the spirit and technical concepts disclosed by the present disclosure should still be covered by the attached claims of the present disclosure.

1. A circuit for digital clock data recovery, comprising:
an analog-to-digital converter, configured to sample an analog input signal under the control of a sampling clock signal to obtain a sampled signal, and convert the sampled signal into a digital signal;
an error detector, configured to perform phase error detection based on the digital signal to obtain one or more phase error estimation values;
a frequency deviation detector, configured to obtain a frequency deviation estimation value based on the phase error estimation values;
a loop filter, configured to filter and output a filtered signal based on the phase error estimation values and the frequency deviation estimation value;
a phase code generator, configured to generate a phase code based on the filtered signal; and
a phase interpolator, configured to generate the sampling clock signal based on the phase code to control a sampling phase of the analog-to-digital converter.

2. The circuit according to claim 1, wherein the phase interpolator adjusts a phase of a local reference clock based on the phase code to generate the sampling clock signal.

3. The circuit according to claim 1, wherein the frequency deviation detector comprises:
a pre-processing unit, configured to pre-process the phase error estimation values to obtain pre-processed phase error estimation values;
a differential calculation unit, configured to obtain a differential sequence based on the pre-processed phase error estimation values; and
a frequency deviation calculation unit, configured to calculate the frequency deviation estimation value based on the differential sequence.

4. The circuit according to claim 3, wherein the differential sequence is an indication signal for occurrences of phase error estimation value jumps.

5. The circuit according to claim 4, wherein the differential calculation unit calculates the indication signal by following formulas:
$$f ( i ) = compare ( s ( i ) - s ( i - τ ) , th 1 ) ; and$$
$$compare ( s ( i ) - s ( i - τ ) , th 1 ) = \{ \begin{matrix}\begin{matrix}sign ( s ( i ) - s ( i - τ ) ) , & if abs ( s ( i ) - s ( i - τ ) ) > th 1\end{matrix} \\ \begin{matrix}0 , & else\end{matrix}\end{matrix} ;$$
where f(i) represents the indication signal, s(i) represents the pre-processed phase error estimation values, th1 represents a first threshold value, t represents a time interval between two adjacent phase error estimation values, and sign represents a symbol function.

6. The circuit according to claim 4, wherein the frequency deviation calculation unit is configured to calculate the frequency deviation estimation value based on an integral of the indication signal over a specific time interval.

7. The circuit according to claim 6, wherein the frequency deviation calculation unit calculates the frequency deviation estimation value by following formulas:
$$Δ frq ( i ) = \{ \begin{matrix}est ( frqdetintg ( i ) ) , if mod ( i , T ) = 0 \\ 0 , else\end{matrix} ;$$
$$frqdetintg ( i ) = frqdetintg ( i - 1 ) + f ( i ) ; and$$
$$est ( frq d e t i n t g ( i ) ) = frqslp * floor ( \frac{frqdetintg ( i )}{frqth} + 0.5 ) ;$$
where Δfrq(i) represents the frequency deviation estimation value, frqdetintg(i) represents an accumulated indication signal for the occurrence of phase error estimation value jumps, f(i) represents the indication signal for the occurrences of phase error estimation value jumps, mod represents a remainder function, T represents the specific time interval, frqslp represents a slope of the integral of the indication signal, floor represents a downward rounding function, and frqth represents an accumulated count threshold for the occurrences of phase error estimation value jumps.

8. The circuit according to claim 4, wherein the frequency deviation calculation unit is configured to calculate the frequency deviation estimation value based on a duration required for integrating the indication signal to an upper limit value or a lower limit value.

9. The circuit according to claim 1, wherein the loop filter is a second-order filter.

10. The circuit according to claim 9, wherein a frequency integral branch of the second-order filter is given by:
$$intg ( i ) = intg ( i - 1 ) + β * t e d ( i ) + Δ f r q ( i ) ;$$
where intg(i) represents an output of the loop filter at moment i, intg(i−1) represents an output of the loop filter at moment (i−1), β represents a coefficient, ted(i) represents the phase error estimation values, and Δfrq(i) represents the frequency deviation estimation value.

11. The circuit according to claim 1, wherein when a detection frequency of the frequency deviation detector reaches a detection threshold and the frequency deviation estimation value is detected to be less than a second threshold, the frequency deviation detector is turned off, and the loop filter obtains the filtered signal based on the phase error estimation values.

12. The circuit according to claim 1, wherein a quantity of the phase error estimation values is more than one, and the frequency deviation detector obtains the frequency deviation estimation value based on an average value of the phase error estimation values.

13. A digital clock data recovery method, applied to a circuit for digital clock data recovery, wherein the circuit comprises an analog-to-digital converter, an error detector, a frequency deviation detector, a loop filter, a phase code generator, and a phase interpolator; wherein the method comprises:
sampling, by the analog-to-digital converter, an analog input signal under the control of a sampling clock signal to obtain a sampled signal, and converting the sampled signal into a digital signal;
performing, by the error detector, phase error detection based on the digital signal to obtain one or more phase error estimation values;
obtaining, by the frequency deviation detector, a frequency deviation estimation value based on the phase error estimation values;
filtering and outputting, by the loop filter, a filtered signal based on the phase error estimation values and the frequency deviation estimation value;
generating, by the phase code generator, a phase code based on the filtered signal; and
generating, by the phase interpolator, the sampling clock signal based on the phase code.
